(19) United States
(12) Patent Application Publication
(10) Pub. No.: US 2025/0017090 A1
(43) Pub. Date: Jan. 9, 2025

(54) DISPLAY DEVICE

(71) Applicant: Samsung Display Co., LTD., Yongin-si (KR)

(72) Inventors: Jae Min SHIN, Yongin-si (KR); Joo Sun YOON, Yongin-si (KR)

(73) Assignee: Samsung Display Co., LTD., Yongin-si (KR)

(21) Appl. No.: 18/756,147

(22) Filed: Jun. 27, 2024

(30) Foreign Application Priority Data
Jul. 6, 2023 (KR) 10-2023-0087723

(51) Int. Cl. H10K 59/80; H10K 59/122

(52) U.S. Cl. CPC H10K 59/8792; H10K 59/122

(57) ABSTRACT

A display device that includes a substrate including a display area and a non-display area, a light emitting element layer disposed on the display area and including a pixel electrode, an organic light emitting layer and a common electrode, a circuit part disposed on the non-display area and including multiple circuit transistors, and a pixel defining layer extending from the display area to the circuit part, wherein the pixel defining layer includes multiple openings overlapping the circuit part, and the openings do not overlap the circuit transistors.

### CROSS-REFERENCE TO RELATED APPLICATIONS

This application claims priority under 35 U.S.C. § 119 from Korean Patent Application No. 10-2023-0087723 filed on Jul. 6, 2023 in the Korean Intellectual Property Office (KIPO), the entire contents of which are incorporated herein by reference.

### BACKGROUND

### 1. Technical Field

The disclosure relates to a display device.

### 2. Description of the Related Art

As the information society develops, demands for display devices for displaying images are increasing in various forms. For example, display devices are applied to various electronic devices such as smartphones, digital cameras, notebook computers, navigation devices, and smart televisions.

The display devices may be flat panel display devices such as liquid crystal display devices, field emission display devices, and light emitting display devices. The light emitting display devices may include an organic light emitting display device including an organic light emitting element, an inorganic light emitting display device including an inorganic light emitting element such as an inorganic semiconductor, and a micro-light emitting display device including a micro-light emitting element.

An organic light emitting element may include two electrodes facing each other and a light emitting layer disposed between them. The light emitting layer may receive electrons and holes from the two electrodes, recombine them to generate excitons, and emit light as the generated excitons change from an excited state to a ground state.

### SUMMARY

Aspects of the disclosure provide a display device which can prevent reliability defects of a circuit part caused by external light.

However, aspects of the disclosure may not be restricted to the one set forth herein. The above and other aspects of the disclosure will become more apparent to one of ordinary skill in the art to which the disclosure pertains by referencing the detailed description of the disclosure given below.

According to an aspect of the disclosure, a display device may include a display area and a non-display area, a light emitting element layer disposed on a substrate in the display area and including a pixel electrode, an organic light emitting layer and a common electrode, a circuit part disposed on the substrate in the non-display area and including a plurality of circuit transistors, and a pixel defining layer extending from the display area to the circuit part, wherein the pixel defining layer may include a plurality of openings overlapping the circuit part, and the openings may not overlap the circuit transistors.

In an embodiment, the pixel defining layer may cover edges of the pixel electrode and may include a black pigment or dye.

In an embodiment, ones of the circuit transistors that do not overlap the openings may overlap the pixel defining layer.

In an embodiment, a distance between any two adjacent openings among the openings vary.

In an embodiment, a distance between any two adjacent openings among the openings may be greater than a distance between two other openings.

In an embodiment, the circuit transistors may include an oxide semiconductor.

In an embodiment, the display device may further include a via layer disposed on the display area and the non-display area and disposed between the substrate and the pixel defining layer, wherein the openings may expose an upper surface of the via layer.

In an embodiment, the common electrode may extend from the display area to the circuit part and may overlap at least some of the circuit transistors.

According to an aspect of the disclosure, a display device may include a display area and a non-display area, a light emitting element layer disposed on a substrate in the display area and including a pixel electrode, an organic light emitting layer and a common electrode, circuit parts disposed on the substrate in the non-display area and including a plurality of circuit transistors, and a pixel defining layer extending from the display area to the circuit parts, wherein the common electrode may extend from the display area to the circuit parts, the pixel defining layer may include a plurality of openings overlapping the circuit parts, some of the circuit transistors may overlap the common electrode, and the openings may overlap at least some of the circuit transistors that overlap the common electrode and may not overlap any of the circuit transistors that do not overlap the common electrode.

In an embodiment, the circuit parts may include a first circuit part disposed adjacent to the display area and a second circuit part spaced farther apart from the display area than the first circuit part, wherein the first circuit part may include a plurality of first circuit transistors, and the common electrode may overlap the first circuit transistors.

In an embodiment, the second circuit part may include (2-1)th circuit transistors adjacent to the first circuit part and (2-2)th circuit transistors disposed adjacent to an outer side of the substrate from the (2-1)th circuit transistors, and the common electrode may overlap the (2-1)th circuit transistors and may not overlap the (2-2)th circuit transistors.

In an embodiment, the openings may overlap at least some of the first circuit transistors and may overlap at least some of the (2-1)-th circuit transistors.

In an embodiment, the openings may not overlap the (2-2)th circuit transistors.

According to an aspect of the disclosure, a display device may include a display area and a non-display area, a light emitting element layer disposed on a substrate in the display area and including a pixel electrode, an organic light emitting layer and a common electrode, circuit parts disposed on the substrate in the non-display area and including a plurality of circuit transistors, and a pixel defining layer extending from the display area to the circuit parts and including a plurality of openings overlapping the circuit parts, wherein the plurality of openings may overlap some of the plurality of circuit transistors and do not overlap the other circuit transistors.

In an embodiment, the circuit parts may include a first circuit part disposed adjacent to the display area and a second circuit part spaced farther apart from the display area than the first circuit part, wherein each of the first circuit part and the second circuit part may include at least buffer transistors, and the buffer transistors may not overlap the openings.

In an embodiment, each of the first circuit part and the second circuit part may further include switching transistors, and some of the switching transistors of each of the first circuit part and the second circuit part may overlap ones of the plurality of openings, and the other switching transistors may overlap the pixel defining layer.

In an embodiment, the common electrode may extend from the display area to overlap the first circuit part and the second circuit part, the buffer transistors disposed in the first circuit part may overlap the common electrode, and at least some of the buffer transistors disposed in the second circuit part may not overlap the common electrode.

In an embodiment, the circuit transistors may include an oxide semiconductor.

In an embodiment, the display device may further include a via layer disposed between the substrate and the pixel defining layer and covering the circuit transistors, and a connection line disposed between the pixel defining layer and the via layer and overlapping the circuit transistors.

In an embodiment, the display device may further include a thin-film encapsulation layer disposed on the light emitting element layer and extending from the display area to the non-display area, wherein the thin-film encapsulation layer may overlap the circuit transistors.

In a display device according to an embodiment, openings of a pixel defining layer may not overlap circuit transistors disposed in a circuit part in a non-display area. Therefore, the circuit transistors can be prevented from being deteriorated by external light.

Circuit transistors overlapping a common electrode in the non-display area may overlap the openings, and circuit transistors that do not overlap the common electrode do not overlap the openings. Therefore, the circuit transistors can be prevented from being deteriorated by external light.

The openings of the pixel defining layer do not overlap buffer transistors among the circuit transistors disposed in the circuit part in the non-display area. Therefore, the buffer transistors can be prevented from being deteriorated by external light.

However, the effects of the embodiments may not be restricted to the one set forth herein. The above and other effects of the embodiments will become more apparent to one of daily skill in the art to which the embodiments pertain by referencing the claims.

### BRIEF DESCRIPTION OF THE DRAWINGS

These and/or other aspects will become apparent and more readily appreciated from the following description of the embodiments, taken in conjunction with the accompanying drawings in which:

FIG. 1 is a plan view of a display device according to an embodiment;

FIG. 2 is a schematic cross-sectional view taken along line Q1-Q1′ of FIG. 1;

FIG. 3 is a detailed plan view of an example of a display portion of FIG. 2;

FIG. 4 is a schematic diagram of an equivalent circuit of a pixel of the display device according to the embodiment;

FIG. 5 is a schematic cross-sectional view taken along line Q2-Q2′ of FIG. 3;

FIG. 6 is an enlarged plan view of area A of FIG. 3;

FIG. 7 is a schematic cross-sectional view taken along line Q3-Q3′ of FIG. 6;

FIG. 8 is a schematic cross-sectional view taken along line Q4-Q4′ of FIG. 6;

FIG. 9 is a schematic cross-sectional view taken along line Q5-Q5′ of FIG. 6;

FIG. 10 is a plan view of a non-display area of a display device according to an embodiment;

FIG. 11 is a schematic cross-sectional view taken along line Q6-Q6′ of FIG. 10;

FIG. 12 is a schematic cross-sectional view taken along line Q7-Q7′ of FIG. 10;

FIG. 13 is a schematic cross-sectional view taken along line Q8-Q8′ of FIG. 10;

FIG. 14 is a plan view of a non-display area of a display device according to an embodiment; and

FIG. 15 is a schematic cross-sectional view taken along line Q9-Q9′ of FIG. 14.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments will be described with reference to the accompanying drawings.

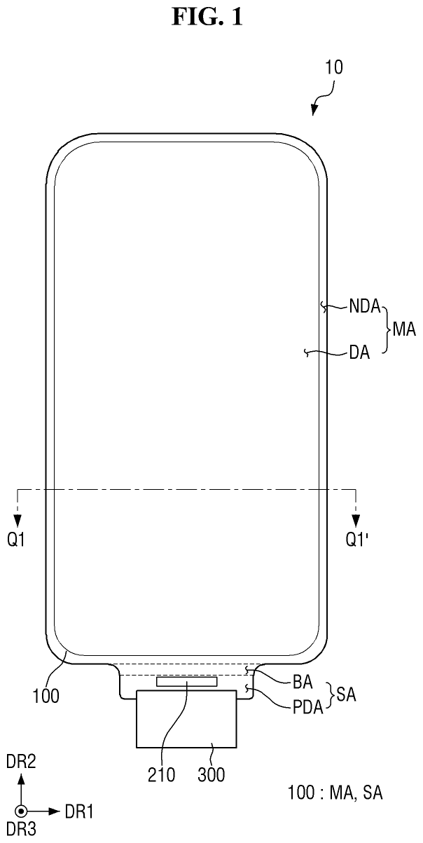

FIG. 1 is a plan view of a display device 10 according to an embodiment.

Referring to FIG. 1, the display device 10 may be a device for displaying moving images or still images. The display device 10 may be used as a display screen in portable electronic devices such as mobile phones, smartphones, tablet personal computers (PCs), smart watches, watch phones, mobile communication terminals, electronic notebooks, electronic books, portable multimedia players (PMPs), navigation devices and ultra-mobile PCs (UMPCs), as well as in various products such as televisions, notebook computers, monitors, billboards and Internet of things (IoT) devices. The display device 10 may be any one of an organic light emitting display device, a liquid crystal display device, a plasma display device, a field emission display device, an electrophoretic display device, an electrowetting display device, a quantum dot light emitting display device, and a micro-light emitting diode display device. A case where the display device 10 may be an organic light emitting display device will be described below, but the disclosure may not be limited thereto.

The display device 10 according to the embodiment may include a display panel 100, a display driving circuit 210, and a circuit board 300.

The display panel 100 may include a main area MA and a sub-area SA protruding from a side of the main area MA.

The main area MA may be rectangular shaped in a plan view and having short sides in the first direction DR1 and long sides in the second direction DR2 intersecting the first direction DR1. Each corner where a short side extending in the first direction DR1 meets a long side extending in the second direction DR2 may be rounded with a curvature (e.g., predetermined or selectable curvature) or may be right-angled. The planar shape of the display device 10 may not be limited to a quadrilateral shape, but may also be another polygonal shape, a circular shape, or an oval shape. The main area MA may be formed to be flat. However, the disclosure may not be limited thereto, and the main area MA may also include curved portions formed at left and right ends thereof. The curved portions may have a constant curvature or a varying curvature.

The main area MA may include a display area DA where pixels may be formed to display an image and a non-display area NDA located around the display area DA.

In the display area DA, not only pixels, but also scan lines, data lines and power lines electrically connected to the pixels may be disposed. In case that the main area MA includes curved portions, the display area DA may be disposed in the curved portions. An image of the display panel 100 may also be seen in the curved portions.

The non-display area NDA may be defined as an area extending from the outside of the display area DA to edges of the display panel 100. A circuit part for transmitting scan signals and emission control signals and link lines connecting the data lines and the display driving circuit 210 may be disposed in the non-display area NDA.

The sub-area SA may protrude from a side of the main area MA. For example, the sub-area SA may protrude from a lower side of the main area MA as illustrated in FIG. 1. A length of the sub-area SA in the first direction DR1 may be smaller than a length of the main area MA in the first direction DR1.

The sub-area SA may include a bending area BA and a pad area PDA. The pad area PDA may be disposed on a side of the bending area BA, and the main area MA may be disposed on another side of the bending area BA. For example, the pad area PDA may be disposed on a lower side of the bending area BA, and the main area MA may be disposed on an upper side of the bending area BA.

The display panel 100 may be formed to be flexible so that it can be curved, bent, folded, or rolled. Therefore, the display panel 100 can be bent in the bending area BA in the third direction DR3 which may be a thickness direction. A surface of the pad area PDA of the display panel 100 may face upward before the display panel 100 is bent. However, after the display panel 100 is bent, the surface of the pad area PDA of the display panel 100 may face downward. Accordingly, the pad area PDA may be disposed under the main area MA and thus overlapped by the main area MA.

The display driving circuit 210 and pads electrically connected to the circuit board 300 may be disposed in the pad area PDA of the display panel 300.

The display driving circuit 210 outputs signals and voltages for driving the display panel 100. For example, the display driving circuit 210 may supply data voltages to the data lines. The display driving circuit 210 may supply power supply voltages to the power lines and supply scan control signals to the circuit part. The display driving circuit 210 may be formed as an integrated circuit and mounted on the pad area PDA of the display panel 100 using a chip on glass (COG) method, a chip on plastic (COP) method, or an ultrasonic bonding method. However, the disclosure may not be limited thereto. For example, the display driving circuit 210 may also be mounted on the circuit board 300.

The circuit board 300 may be attached onto the pads using an anisotropic conductive film. Therefore, lead lines of the circuit board 300 may be electrically connected to the pads. The circuit board 300 may be a flexible printed circuit board, a printed circuit board, or a flexible film such as a chip on film.

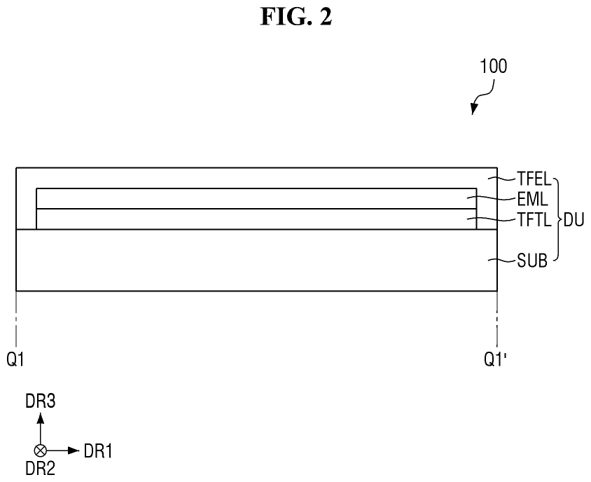

FIG. 2 is a schematic cross-sectional view taken along line Q1-Q1′ of FIG. 1.

Referring to FIG. 2, the display panel 100 may include a display portion DU including a substrate SUB, a thin-film transistor layer TFTL disposed on the substrate SUB, a light emitting element layer EML, and a thin-film encapsulation layer TFEL.

The substrate SUB may be made of an insulating material such as glass, quartz, polymer resin, or a combination thereof. The polymer material may be, for example, polyethersulphone (PES), polyacrylate (PA), polyarylate (PAR), polyetherimide (PEI), polyethylene naphthalate (PEN), polyethylene terephthalate (PET), polyphenylene sulfide (PPS), polyarylate, polyimide (PI), polycarbonate (PC), cellulose triacetate (CAT), cellulose acetate propionate (CAP), or a combination thereof. For example, the substrate SUB may include a metal material.

The substrate SUB may be a rigid substrate or a flexible substrate that can be bent, folded, or rolled. In case that the substrate SUB is a flexible substrate, the substrate SUB may be made of, but not limited to, polyimide (PI).

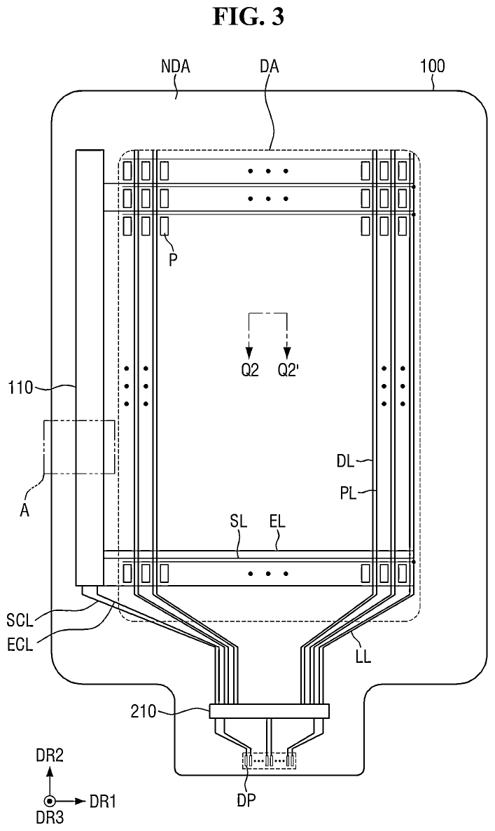

The thin-film transistor layer TFTL may be disposed on the substrate SUB. In the thin-film transistor layer TFTL, not only thin-film transistors of pixels, but also scan lines, data lines, power lines, scan control lines, and routing lines connecting pads and the data lines may be formed. Each of the thin-film transistors may include a gate electrode, a semiconductor layer, a source electrode, and a drain electrode. In case that a circuit part 110 (see FIG. 3) is formed in the non-display area NDA of the display panel 100 as illustrated in FIG. 3, it may include multiple thin-film transistors.

The thin-film transistor layer TFTL may be disposed in the display area DA and the non-display area NDA. Specifically, the thin-film transistors of the pixels, the scan lines, the data lines, and the power lines of the thin-film transistor layer TFTL may be disposed in the display area DA. Emission control lines, scan control lines and link lines of the thin-film transistor layer TFTL may be disposed in the non-display area NDA.

The light emitting element layer EML may be disposed on the thin-film transistor layer TFTL. The light emitting element layer EML may include pixels, each including a first electrode, a light emitting layer and a second electrode, and a pixel defining layer defining the pixels. The light emitting layer may be an organic light emitting layer including an organic material. The light emitting layer may include a hole transporting layer, an organic light emitting layer, and an electron transporting layer. In case that a voltage is (e.g., predetermined or selectable voltage) applied to the first electrode and a cathode voltage is applied to the second electrode through a thin-film transistor of the thin-film transistor layer TFTL, holes and electrons move to the organic light emitting layer through the hole transporting layer and the electron transporting layer, respectively, and combine together in the organic light emitting layer to emit light. The pixels of the light emitting element layer EML may be disposed in the display area DA.

The thin-film encapsulation layer TFEL may be disposed on the light emitting element layer EML. The thin-film encapsulation layer TFEL prevents oxygen or moisture from permeating into the light emitting element layer EML. To this end, the thin-film encapsulation layer TFEL may include at least one inorganic layer. The inorganic layer may include, but may not be limited to, silicon nitride (SiNₓ), silicon oxynitride (SiNₓO_{y}), silicon oxide (SiOₓ), titanium oxide (TiO₂), aluminum oxide (Al₂O₃), or a combination thereof. The thin-film encapsulation layer TFEL also protects the light emitting element layer EML from foreign substances such as dust. To this end, the thin-film encapsulation layer TFEL may include at least one organic layer. The organic layer may be, but may not be limited to, acryl resin, epoxy resin, phenolic resin, polyamide resin, polyimide resin, or a combination thereof.

The thin-film encapsulation layer TFEL may be disposed in both the display area DA and the non-display area NDA. Specifically, the thin-film encapsulation layer TFEL may cover the light emitting element layer EML of the display area DA and the non-display area NDA and cover the thin-film transistor layer TFTL of the non-display area NDA.

A touch sensor layer may be disposed on the thin-film encapsulation layer TFEL. Since the touch sensor layer may be disposed (e.g., directly disposed) on the thin-film encapsulation layer TFEL, a thickness of the display device 10 can be reduced as compared with when a separate touch panel including the touch sensor layer may be attached onto the thin-film encapsulation layer TFEL.

FIG. 3 is a detailed plan view of an example of the display portion DU of FIG. 2.

In FIG. 3, only pixels P, scan lines SL, data lines DL, power lines PL, an emission control line ECL, a scan control line SCL, the circuit part 110, the display driving circuit 210, and display pads DP are illustrated for ease of description.

Referring to FIG. 3, the scan lines SL, the data lines DL, the power lines PL, and the pixels P may be disposed in the display area DA. The scan lines SL may extend parallel to each other in the first direction DR1, and the data lines DL may extend parallel to each other in the second direction DR2 intersecting the first direction DR1. The power lines PL may include at least one line extending parallel to the data lines DL in the second direction DR2 and multiple lines branching from the at least one line in the first direction DR1.

Each of the pixels P may be electrically connected to at least any one of the scan lines SL, any one of the data lines DL, and a power line PL. Each of the pixels P may include thin-film transistors including a driving transistor and at least one switching transistor, an organic light emitting diode, and a capacitor. Each of the pixels P may receive a data voltage of a data line DL in response to a scan signal transmitted from a scan line SL and supply a driving current to the organic light emitting diode according to the data voltage applied to a gate electrode of a driving transistor, thereby emitting light.

The circuit part 110 may be electrically connected to the display driving circuit 210 through the scan control line SCL and the emission control line ECL. The circuit part 110 generates scan signals and emission signals in response to a scan control signal and an emission control signal received from the display driving circuit 210 and supplies the scan signals and the emission signals to the scan lines SL and emission lines EL, respectively.

Although the circuit part 110 may be formed in the non-display area NDA outside a left side of the display area DA in FIG. 3, the disclosure may not be limited thereto. For example, the circuit part 110 may also be formed in the non-display area NDA outside left and right sides of the display area DA.

The display driving circuit 210 may be electrically connected to the display pads DP to receive digital video data and timing signals. The display driving circuit 210 converts the digital video data into analog positive/negative data voltages and supplies the analog positive/negative data voltages to the data lines DL through link lines LL. The display driving circuit 210 generates a scan control signal and an emission control signal for controlling the circuit part 110 and supplies the scan control signal and the emission control signal to the circuit part 110 through the scan control line SCL and the emission control line ECL, respectively. Pixels P to be supplied with the data voltages may be selected by scan signals of the circuit part 110, and the data voltages may be supplied to the selected pixels P. Emission control voltages may be supplied by emission control signals of the circuit part 110. The display driving circuit 210 may be formed as an integrated circuit and attached onto the substrate SUB using a COG method, a COP method, or an ultrasonic bonding method.

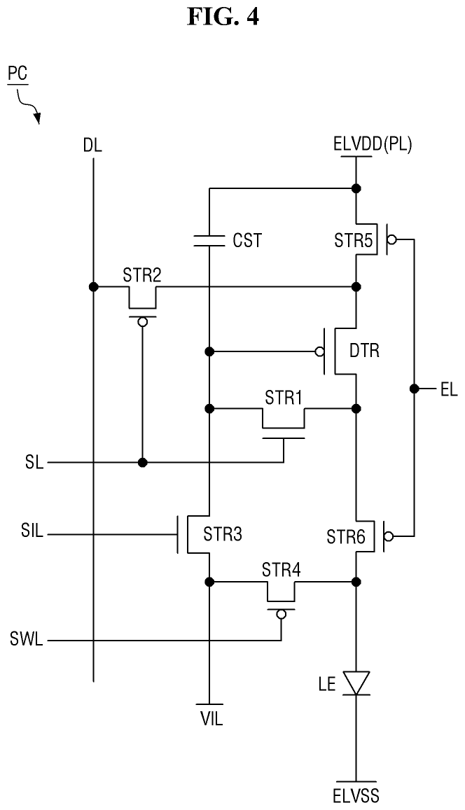

FIG. 4 is a schematic diagram of an equivalent circuit of a pixel of the display device 10 according to the embodiment.

Referring to FIG. 4, a pixel circuit PC may include a driving transistor DTR and first through sixth transistors STR1 through STR6. A first electrode of the driving transistor DTR may be electrically connected to a light emitting diode LE via the sixth transistor STR6. The driving transistor DTR receives a data signal according to a switching operation of the second transistor STR2 and supplies a driving current to the light emitting diode LE.

A gate electrode of the first transistor STR1 may be electrically connected to a scan line SL. A first electrode of the first transistor STR1 may be electrically connected to the first electrode of the driving transistor DTR and may be electrically connected to a pixel electrode of the light emitting diode LE via the sixth transistor STR6. A second electrode of the first transistor STR1 may be electrically connected to a first electrode of a capacitor CST, a first electrode of the third transistor STR3, and a gate electrode of the driving transistor DTR. The first transistor STR1 may be turned on according to a scan signal received through the scan line SL and connects the gate electrode and drain electrode of the driving transistor DTR to each other to drive the driving transistor DTR.

A gate electrode of the second transistor STR2 may be electrically connected to the scan line SL, and a first electrode of the second transistor STR2 may be electrically connected to a data line DL. A second electrode of the second transistor STR2 may be electrically connected to a second electrode of the driving transistor DTR and may be electrically connected to a power line PL via the fifth transistor STR5. The second transistor STR2 may be turned on according to the scan signal received through the scan line SL and performs a switching operation to transmit a data signal received through the data line DL to the second electrode of the driving transistor DTR.

A gate electrode of the third transistor STR3 may be electrically connected to a scan initialization line SIL. A second electrode of the third transistor STR3 may be electrically connected to an initialization voltage line VIL. The first electrode of the third transistor STR3 may be electrically connected to the first electrode of the capacitor CST, the second electrode of the first transistor STR1, and the gate electrode of the driving transistor DTR. The third transistor STR3 may be turned on according to a scan initialization signal received through the scan initialization line SIL and may transmit an initialization voltage to the gate electrode of the driving transistor DTR to initialize the voltage of the gate electrode of the driving transistor DTR.

A gate electrode of the fourth transistor STR4 may be electrically connected to a scan write line SWL. A first electrode of the fourth transistor STR4 may be electrically connected to the pixel electrode of the light emitting diode LE. A second electrode of the fourth transistor STR4 may be electrically connected to the initialization voltage line VIL. The fourth transistor STR4 may be turned on according to a scan write signal received through the scan write line SWL and may initialize the pixel electrode of the light emitting diode LE.

A gate electrode of the fifth transistor STR5 may be electrically connected to an emission line EL. A first electrode of the fifth transistor STR5 may be electrically connected to the power line PL. A second electrode of the fifth transistor STR5 may be electrically connected to the second electrode of the driving transistor DTR and the second electrode of the second transistor STR2.

A gate electrode of the sixth transistor STR6 may be electrically connected to the emission line EL. A first electrode of the sixth transistor STR6 may be electrically connected to the first electrode of the driving transistor DTR and the first electrode of the first transistor STR1. A second electrode of the sixth transistor STR6 may be electrically connected to the pixel electrode of the light emitting diode LE. The fifth transistor STR5 and the sixth transistor STR6 may be simultaneously turned on according to an emission signal received through the emission line EL and allow a first power supply voltage ELVDD to be transmitted to the light emitting diode LE and to allow a driving current to flow through the light emitting diode LE.

The first electrode of the capacitor CST may be electrically connected to the gate electrode of the driving transistor DTR, the second electrode of the first transistor STR1, and the first electrode of the third transistor STR3.

A common electrode of the light emitting diode LE receives a second power supply voltage ELVSS. The light emitting diode LE emits light in response to a driving current received from the driving transistor DTR.

The pixel circuit PC described above may not be limited to FIG. 4, and the number of transistors and capacitors and circuit design can be variously changed.

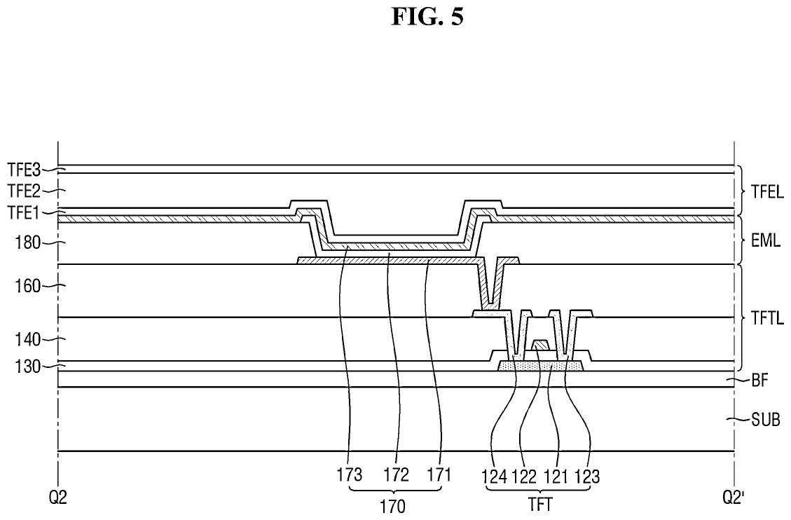

FIG. 5 is a schematic cross-sectional view taken along line Q2-Q2′ of FIG. 3.

Referring to FIG. 5, the thin-film transistor layer TFTL may be disposed on the substrate SUB. The thin-film transistor layer TFTL may include a transistor TFT, a gate insulating layer 130, an interlayer insulating layer 140, and a via layer 160.

Specifically, a buffer layer BF may be disposed on a surface of the substrate SUB. The buffer layer BF may be formed on the surface of the substrate SUB to protect the transistor TFT and an organic light emitting layer 172 of the light emitting element layer EML from moisture introduced through the substrate SUB which may be vulnerable to moisture penetration. The buffer layer BF may be composed of multiple inorganic layers stacked alternately on each other. For example, the buffer layer BF may be a multilayer in which one or more inorganic layers selected from silicon nitride (SiNₓ), silicon oxynitride (SiNₓO_{y}), silicon oxide (SiOₓ), titanium oxide (TiO₂), aluminum oxide (Al₂O₃), and a combination thereof may be alternately stacked on each other. However, the disclosure may not be limited thereto, and the buffer layer BF can also be omitted.

The transistor TFT may be disposed on the buffer layer BF. The transistor TFT may include an active layer 121, a gate electrode 122, a source electrode 123, and a drain electrode 124. In FIG. 5, the transistor TFT may be formed as a top gate structure in which the gate electrode 122 may be located above the active layer 121. However, the disclosure may not be limited thereto. The transistor TFT may also be formed in a bottom gate structure in which the gate electrode 122 may be located below the active layer 121 or a double gate structure in which the gate electrode 122 may be located both above and below the active layer 121.

The active layer 121 may be disposed on the buffer layer BF. The active layer 121 may include polycrystalline silicon, monocrystalline silicon, low-temperature polycrystalline silicon, amorphous silicon, an oxide semiconductor, or a combination thereof. For example, the oxide semiconductor may include a binary compound (ABₓ), a ternary compound (ABₓC_{y}) or a quaternary compound (ABₓC_{y}D_{z}) containing indium (In), zinc (Zn), gallium (Ga), tin (Sn), titanium (Ti), aluminum (Al), hafnium (Hf), zirconium (Zr), magnesium (Mg), etc. For example, the active layer 121 may include ITZO (an oxide including indium, tin, and zinc) or IGZO (an oxide including indium, gallium, and zinc). A light blocking layer may be further disposed between the buffer layer BF and the active layer 121 to block external light from entering the active layer 121.

The gate insulating layer 130 may be disposed on the active layer 121. The gate insulating layer 130 may include any one or more of silicon nitride (SiNₓ), silicon oxynitride (SiNₓO_{y}), silicon oxide (SiOₓ), titanium oxide (TiO₂), and aluminum oxide (Al₂O₃).

The gate electrode 122 may be disposed on the gate insulating layer 130. The gate electrode 122 may be a single layer or a multilayer made of any one or more of molybdenum (Mo), aluminum (Al), chromium (Cr), gold (Au), titanium (Ti), nickel (Ni), neodymium (Nd), copper (Cu), and alloys thereof. Although not illustrated, the gate electrode 122 and a scan line may be disposed on a same layer.

The interlayer insulating layer 140 may be disposed on the gate electrode 122. The interlayer insulating layer 140 may include any one or more of silicon nitride (SiNₓ), silicon oxynitride (SiNₓO_{y}), silicon oxide (SiOₓ), titanium oxide (TiO₂), and aluminum oxide (Al₂O₃).

The source electrode 123 and the drain electrode 124 may be disposed on the interlayer insulating layer 140. Each of the source electrode 123 and the drain electrode 124 may be electrically connected to the active layer 121 through a contact hole passing through the gate insulating layer 130 and the interlayer insulating layer 140. Each of the source electrode 123 and the drain electrode 124 may be a single layer or a multilayer made of any one or more of molybdenum (Mo), aluminum (Al), chromium (Cr), gold (Au), titanium (Ti), nickel (Ni), neodymium (Nd), copper (Cu), and alloys thereof.

The via layer 160 may be disposed on the source electrode 123 and the drain electrode 124 to flatten a step difference due to the transistor TFT. The via layer 160 may include acryl resin, epoxy resin, phenolic resin, polyamide resin, polyimide resin, the like, or a combination thereof.

The light emitting element layer EML may be disposed on the thin-film transistor layer TFTL. The light emitting element layer EML may include a light emitting element 170 and a pixel defining layer 180.

The light emitting element 170 and the pixel defining layer 180 may be disposed on the via layer 160. The light emitting element 170 may include a pixel electrode 171, the organic light emitting layer 172, and a common electrode 173.

The pixel electrode 171 may be disposed (e.g., directly disposed) on the via layer 160. The pixel electrode 171 may be electrically connected to the source electrode 123 of the transistor TFT through a contact hole passing through the via layer 160.

In a top emission structure in which light may be emitted from the organic light emitting layer 172 toward the common electrode 173, the pixel electrode 171 may be made of a metal material having high reflectivity, such as a stacked structure (Ti/AV/Ti) of aluminum and titanium, a stacked structure (ITO/Al/ITO) of aluminum and indium tin oxide, an APC alloy, or a stacked structure (ITO/APC/ITO) of an APC alloy and indium tin oxide. The APC alloy may be an alloy of silver (Ag), palladium (Pd), and copper (Cu).

In a bottom emission structure in which light may be emitted from the organic light emitting layer 172 toward the pixel electrode 171, the pixel electrode 171 may be made of a transparent conductive material (TCO) capable of transmitting light, such as indium tin oxide (ITO) or indium zinc oxide (IZO), or a semi-transmissive conductive material such as magnesium (Mg), silver (Ag) or an alloy of Mg and Ag, or a combination thereof. In case that the pixel electrode 171 may be made of a semi-transmissive conductive material, light output efficiency may be increased by a microcavity.

The pixel defining layer 180 may define the pixel electrode 171 on the via layer 160 to define an emission area. The pixel defining layer 180 may be formed to cover edges of the pixel electrode 171. The pixel defining layer 180 may be made of an organic layer such as acryl resin, epoxy resin, phenolic resin, polyamide resin, polyimide resin, or a combination thereof. The pixel defining layer 180 may include a black pigment or dye to reduce reflection of external light and prevent color mixing. For example, the pixel defining layer 180 may include carbon black.

The organic light emitting layer 172 may be disposed on the pixel electrode 171 and the pixel defining layer 180. The organic light emitting layer 172 may include an organic material to emit light of a color (e.g., predetermined or selectable color). For example, the organic light emitting layer 172 may include a hole transporting layer, an organic material layer, and an electron transporting layer. The organic light emitting layer 172 may emit red, green, or blue light. However, the disclosure may not be limited thereto, and the organic light emitting layer 172 may also emit white light.

The common electrode 173 may be disposed on the organic light emitting layer 172. The common electrode 173 may be formed to cover the organic light emitting layer 172. The common electrode 173 may be a common layer formed over the entire display area DA.

In the top emission structure, the common electrode 173 may be made of a transparent conductive material (TCO) capable of transmitting light, such as ITO or IZO, or a semi-transmissive conductive material such as magnesium (Mg), silver (Ag), or an alloy of magnesium (Mg) and silver (Ag), or a combination thereof. In case that the common electrode 173 may be made of a semi-transmissive conductive material, light output efficiency may be increased by a microcavity.

In the bottom emission structure, the common electrode 173 may be made of a metal material having high reflectivity, such as a single layer of aluminum, a stacked structure (Ti/Al/Ti) of aluminum and titanium, a stacked structure (ITO/AVITO) of aluminum and indium tin oxide, an APC alloy, or a stacked structure (ITO/APC/ITO) of an APC alloy and indium tin oxide. The APC alloy may be an alloy of silver (Ag), palladium (Pd), and copper (Cu).

The thin-film encapsulation layer TFEL may be disposed on the light emitting element layer EML. The thin-film encapsulation layer TFEL may be disposed on the common electrode 173. The thin-film encapsulation layer TFEL may include at least one inorganic layer to prevent permeation of oxygen or moisture into the organic light emitting layer 172 and the common electrode 173. The thin-film encapsulation layer TFEL may include at least one organic layer to protect the light emitting element layer EML from foreign substances such as dust.

The thin-film encapsulation layer TFEL may include a first encapsulation layer TFE1, a second encapsulation layer TFE2, and a third encapsulation layer TFE3. Each of the first encapsulation layer TFE1 and the third encapsulation layer TFE3 may be an inorganic layer. The inorganic layer may include, but may not be limited to, silicon nitride (SiNₓ), silicon oxynitride (SiNₓO_{y}), silicon oxide (SiOₓ), titanium oxide (TiO₂), aluminum oxide (Al₂O₃), or a combination thereof. The second encapsulation layer TFE2 may be an organic layer. The organic layer may include, but may not be limited to, acryl resin, epoxy resin, phenolic resin, polyamide resin, polyimide resin, or a combination thereof.

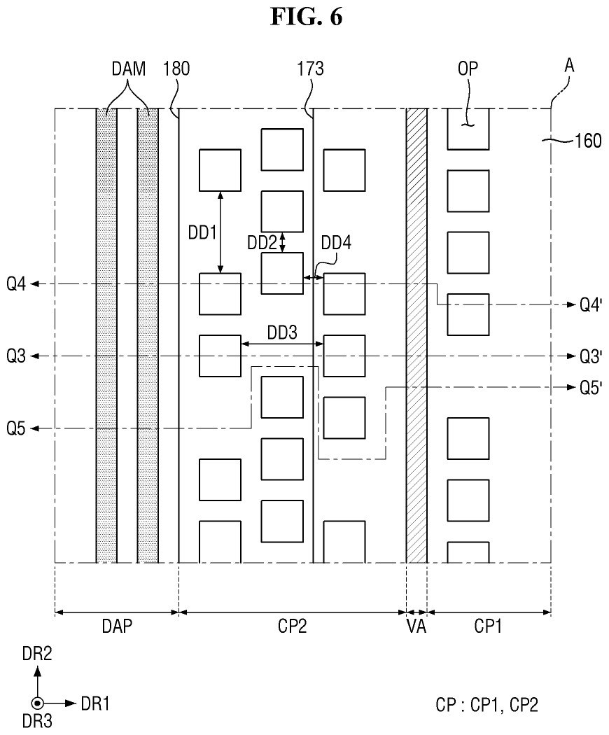

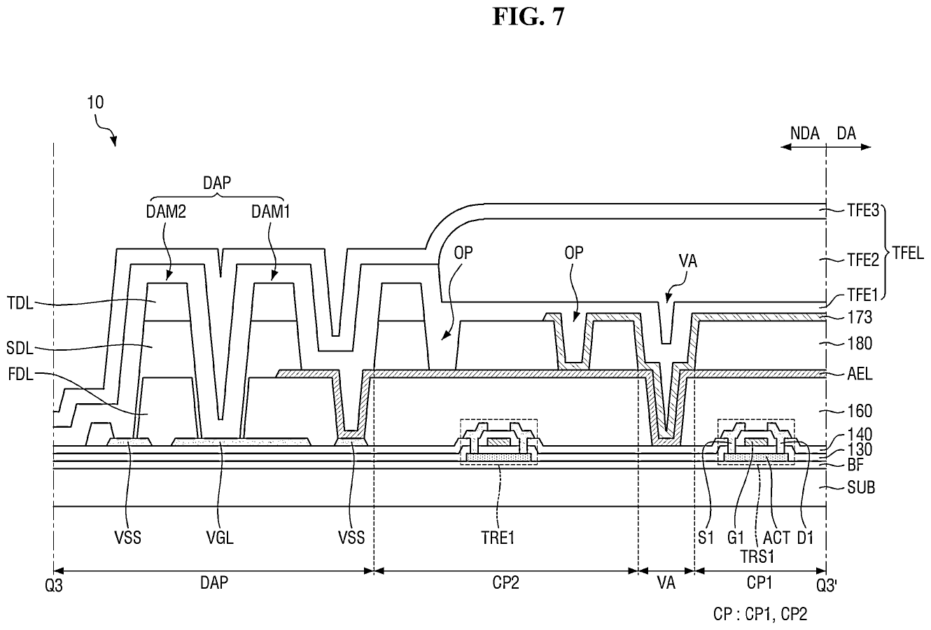

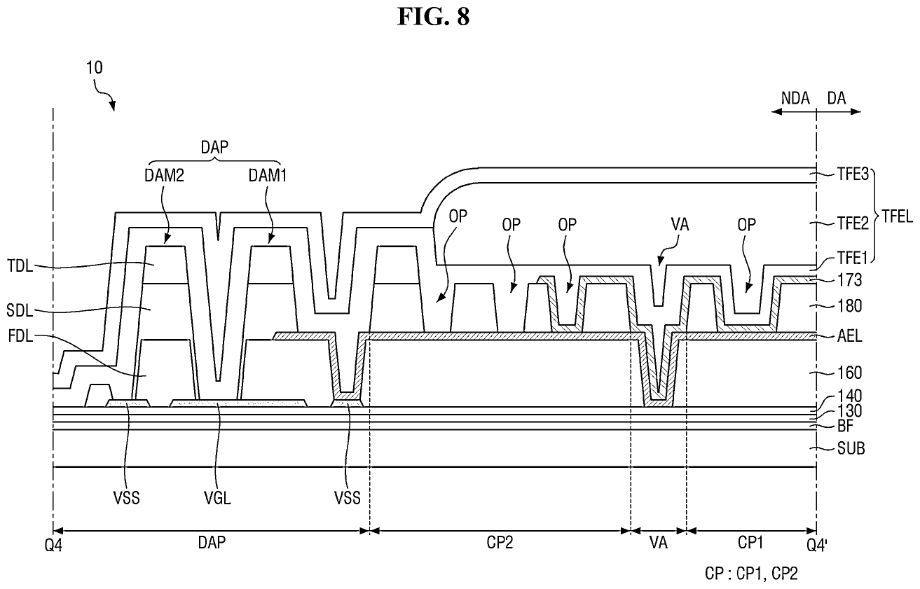

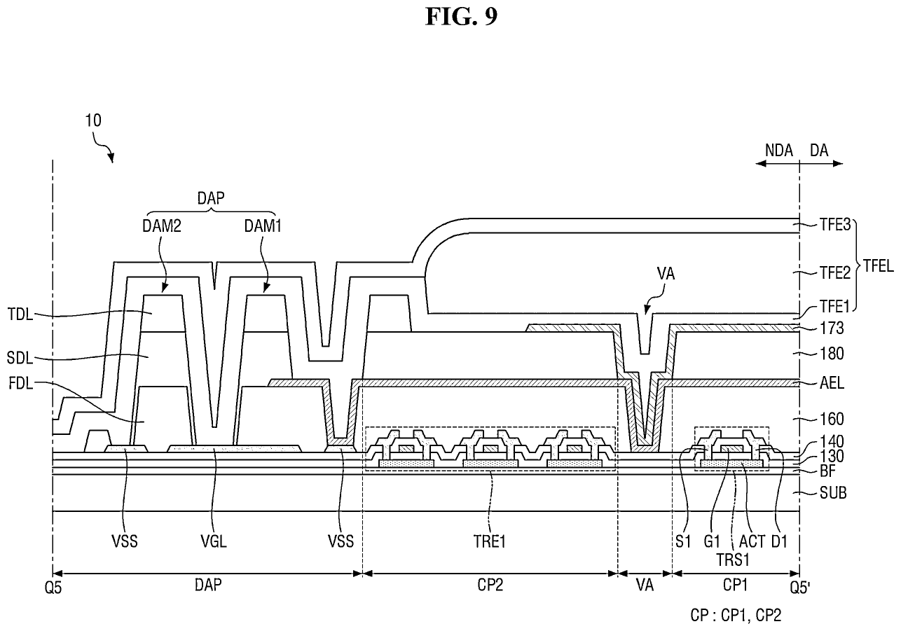

FIG. 6 is an enlarged plan view of area A of FIG. 3. FIG. 7 is a schematic cross-sectional view taken along line Q3-Q3′ of FIG. 6. FIG. 8 is a schematic cross-sectional view taken along line Q4-Q4′ of FIG. 6. FIG. 9 is a schematic cross-sectional view taken along line Q5-Q5′ of FIG. 6.

Referring to FIG. 6, the display device 10 may include the non-display area NDA. The non-display area NDA may include circuit parts CP and a dam part DAP and may include a groove part VA disposed between the circuit parts CP.

The circuit parts CP may be electrically connected to the scan lines SL (see FIG. 3) and the emission control line ECL (see FIG. 3) to transmit signals to the display area DA. The circuit parts CP may be disposed adjacent to the display area DA and may extend in the second direction DR2. The circuit parts CP may include a first circuit part CP1 and a second circuit part CP2.

The first circuit part CP1 may be an area adjacent to the display area DA and may be disposed between the display area DA and the groove part VA. The first circuit part CP1 may include at least one transistor. In an embodiment, the first circuit part CP1 may transmit scan signals to the display area DA. The first circuit part CP1 may be electrically connected to scan lines.

The second circuit part CP2 may be disposed in an area farther from the display area DA than the first circuit part CP1 and may be disposed between the groove part VA and the dam part DAP. The second circuit part CP2 may include at least one transistor. In an embodiment, the second circuit part CP2 may transmit emission control signals to the display area DA. The second circuit part CP2 may be electrically connected to emission control lines.

The groove part VA may be disposed between the first circuit part CP1 and the second circuit part CP2. The groove part VA may separate the first circuit part CP1 and the second circuit part CP2 from each other. The groove part VA may be disposed in the non-display area NDA to surround the display area DA. In an embodiment, the groove part VA may be shaped like a closed loop completely surrounding the display area DA. The groove part VA may separate an organic insulating layer disposed in the non-display area NDA to block moisture that may permeate into the display area DA.

The dam part DAP may be disposed on an outermost side of the display device 10. The dam part DAP may surround the display area DA, together with the circuit parts CP. For example, the dam part DAP may be shaped like a closed loop completely surrounding the display area DA. The dam part DAP may prevent the second encapsulation layer TFE2 of the thin-film encapsulation layer TFEL (see FIG. 3) from overflowing to the outside. The dam part DAP may include at least one dam DAM.

The pixel defining layer 180 and the common electrode 173 extending from the display area DA may be disposed in the non-display area NDA. The pixel defining layer 180 may extend from the display area DA to the circuit parts CP of the non-display area NDA. The common electrode 173 may extend from the display area DA to a portion of the circuit parts CP of the non-display area NDA.

The pixel defining layer 180 described above may include an organic material. Due to the characteristics of the organic material, the organic material inside the pixel defining layer 180 may evaporate to generate a gas during a heat treatment process for manufacturing the display device 10. The gas generated inside the pixel defining layer 180 may weaken adhesion of layers formed on the pixel defining layer 180, thereby causing a peeling problem.

In the current embodiment, the pixel defining layer 180 may include multiple openings OP in the non-display area NDA. The openings OP may serve as passages through which the gas generated by the pixel defining layer 180 may be released. The openings OP may be disposed in the circuit parts CP. For example, the openings OP may be disposed in the first circuit part CP1 and the second circuit part CP2. The openings OP may be arranged in rows and columns. For example, the openings OP may be spaced apart from each other in the first direction DR1 and the second direction DR2.

Multiple transistors may be disposed in the circuit parts CP. Each of the transistors may include an active layer including an oxide semiconductor. In case that the oxide semiconductor is irradiated with light, a threshold voltage of a transistor shifts in a negative direction. Specifically, in case that negative bias illumination stress (NBIS) is applied to the oxide semiconductor irradiated with light, holes may be accumulated at an interface between a gate electrode and a channel. The holes accumulated at the interface may be trapped or injected into an interface trap or a gate insulating layer to shift the threshold voltage in the negative direction. Therefore, even if the NBIS is removed, the negative shift of the threshold voltage cannot be restored to an original state, leading to deterioration of the oxide semiconductor. The deterioration of the oxide semiconductor may reduce driving reliability of the transistor and cause driving failure of the display device 10.

As described above, the black pixel defining layer 180 may have multiple openings OP formed on the circuit parts CP. Since the black pixel defining layer 180 does not exist in the openings OP, the openings OP may serve as incident paths of light from the outside. Accordingly, transistors of the circuit parts CP which overlap the openings OP may deteriorate.

The cross-sectional structure of the display device 10 which can improve driving reliability of the transistors of the circuit parts CP will now be described with reference to FIGS. 7 through 9 in addition to FIG. 6.

Referring to FIGS. 7 through 9, the circuit parts CP, the groove part VA, and the dam part DAP may be disposed on the substrate SUB in the non-display area NDA of the display device 10.

Specifically, the buffer layer BF may be disposed on the substrate SUB, and a first circuit transistor TRS1 and a second circuit transistor TRE1 may be disposed on the buffer layer BF. The first circuit transistor TRS1 may be disposed in the first circuit part CP1, and the second circuit transistor TRE1 may be disposed in the second circuit part CP2. The first circuit transistor TRS1 may be a transistor that transmits a scan signal, and the second circuit transistor TRE1 may be a transistor that transmits an emission control signal. Each of the first circuit transistor TRS1 and the second circuit transistor TRE1 may include an active layer ACT, a gate electrode G1, a source electrode S1, and a drain electrode D1. The active layer ACT may be disposed on the buffer layer BF, the gate electrode G1 may be disposed on the gate insulating layer 130, and the source electrode S1 and the drain electrode D1 may be disposed on the interlayer insulating layer 140. In the drawings, one first circuit transistor TRS1 may be disposed in the first circuit part CP1, and three second circuit transistors TRE1 may be disposed in the second circuit part CP2. However, the disclosure may not be limited thereto, and it may be understood that multiple circuit transistors may be disposed in each of the circuit parts CP1 and CP2.

A second power line VSS and a scan signal line VGL may be disposed on the substrate SUB outside the circuit parts CP. The second power line VSS and the scan signal line VGL may be disposed on the interlayer insulating layer 140 and spaced apart from each other. The second power line VSS may be electrically connected to the common electrode 173 of the display area DA, and the scan signal line VGL may be electrically connected to the first circuit transistor TRS1 of the first circuit part CP1.

The via layer 160 may be disposed on the first circuit transistor TRS1, the second circuit transistor TRE1, the second power line VSS, and the scan signal line VGL. The via layer 160 may extend from the display area DA to the non-display area NDA. The via layer 160 may extend in the circuit parts CP and the dam part DAP.

A connection line AEL may be disposed on the via layer 160. The connection line AEL may extend from the display area DA to the non-display area NDA. The connection line AEL may include a same material as the pixel electrode 171 of the display area DA. The connection line AEL may extend to the second power line VSS of the non-display area NDA and may be electrically connected to the second power line VSS through contact holes formed in the via layer 160. The connection line AEL may electrically connect the second power line VSS and the common electrode 173. The connection line AEL may be disposed on the circuit parts CP and may overlap the circuit transistors TRS1 and TRE1.

The pixel defining layer 180 may be disposed on the via layer 160 and the connection line AEL. The pixel defining layer 180 may extend from the display area DA to the non-display area NDA. The pixel defining layer 180 may overlap the circuit parts CP. In an embodiment, the pixel defining layer 180 may overlap the first circuit part CP1 and the second circuit part CP2.

The groove part VA may be disposed between the first circuit part CP1 and the second circuit part CP2. The groove part VA may be formed in the via layer 160 and the pixel defining layer 180. For example, the groove part VA may pass through the via layer 160 and the pixel defining layer 180 to expose the interlayer insulating layer 140 thereunder. The groove part VA may separate the via layer 160 and the pixel defining layer 180 including an organic material to prevent moisture which may be introduced from the outside from permeating into the display area DA.

The common electrode 173 may be disposed on the pixel defining layer 180. The common electrode 173 may extend from the display area DA to the non-display area NDA. For example, the common electrode 173 may be disposed on the first circuit part CP1, the groove part VA, and the second circuit part CP2. The common electrode 173 may extend to at least a portion of the second circuit part CP2. The common electrode 173 may be electrically connected to the connection line AEL thereunder through an opening OP formed in the pixel defining layer 180. Therefore, the common electrode 173 may be electrically connected to the second power line VSS through the connection line AEL.

The dam part DAP may be disposed outside the circuit parts CP. The dam part DAP may include a first dam DAM1 and a second dam DAM2. In the current embodiment, the dam part DAP may be illustrated and described as including two dams. However, the disclosure may not be limited thereto, and the dam part DAP may also include one dam or three or more dams. The first dam DAM1 and the second dam DAM2 may be spaced apart from each other to prevent the second encapsulation layer TFE2 of the thin-film encapsulation layer TFEL from overflowing from the display area DA to the outside.

Each of the first dam DAM1 and the second dam DAM2 may include a first layer FDL, a second layer SDL, and a third layer TDL. The first layer FDL and the via layer 160 may include a same material, and the second layer SDL and the pixel defining layer 180 may include a same material. The third layer TDL and a spacer formed in the display area DA may include a same material. Although not illustrated, the spacer may be a layer disposed on the pixel defining layer 180 of the display area DA and may support a mask during a mask process for forming the organic light emitting layer 172.

The thin-film encapsulation layer TFEL may be disposed on the pixel defining layer 180, the common electrode 173, and the dam part DAP. The thin-film encapsulation layer TFEL may extend from the display area DA to the non-display area NDA. The thin-film encapsulation layer TFEL may cover the circuit parts CP and overlap the circuit transistors TRS1 and TRE1 disposed in the circuit parts CP.

The first encapsulation layer TFE1 and the third encapsulation layer TFE3 may extend to the dam part DAP via the circuit parts CP. The first encapsulation layer TFE1 and the third encapsulation layer TFE3 may cover the dam part DAP to contact (e.g., directly contact) the interlayer insulating layer 140 on an outermost side of the substrate SUB. The second encapsulation layer TFE2 may be disposed on the circuit parts CP and the groove part VA. The second encapsulation layer TFE2 may not extend to the dam part DAP.

The pixel defining layer 180 may include multiple openings OP. The openings OP may be disposed in the circuit parts CP. For example, the openings OP may be disposed in the first circuit part CP1 and the second circuit part CP2.

The openings OP may be spaced apart from each other in the first direction DR1 and the second direction DR2 and may be repeatedly disposed in row and column directions. The openings OP may be irregularly disposed in a plan view. For example, at least some of the openings OP may be disposed at equal intervals in the first direction DR1 and the second direction DR2 in a plan view, and other openings OP may be disposed at different intervals in the first direction DR1 or the second direction DR2.

In an embodiment, a first distance DD1 measured in the second direction DR2 between two adjacent openings OP may be different from a second distance DD2 measured in the second direction DR2 between two other adjacent openings OP spaced apart from the above two adjacent openings OP in the first direction DR1. For example, the first distance DD1 measured in the second direction DR2 between two adjacent openings OP may be greater than the second distance DD2 measured in the second direction DR2 between two other adjacent openings OP spaced apart from the above two adjacent openings OP in the first direction DR1.

A third distance DD3 measured in the first direction DR1 between two adjacent openings OP may be different from a fourth distance DD4 measured in the first direction DR1 between two other adjacent openings OP spaced apart from the above two adjacent openings OP in the second direction DR2. For example, the third distance DD3 measured in the first direction DR1 between two adjacent openings OP may be greater than the fourth distance DD4 measured in the first direction DR1 between two other adjacent openings OP spaced apart from the above two adjacent openings in the second direction DR2.

In an embodiment, the openings OP may not overlap the transistors disposed in the circuit parts CP. Specifically, the openings OP may not overlap the first circuit transistor TRS1 disposed in the first circuit part CP1 and may not overlap the second circuit transistor TRE1 disposed in the second circuit part CP2. The first circuit transistor TRS1 and the second circuit transistor TRE1 may overlap the pixel defining layer 180.

As described above, the openings OP formed in the pixel defining layer 180 may serve as incident paths of external light. Therefore, if the openings OP overlap the first and second circuit transistors TRS1 and TRE1, the first and second circuit transistors TRS1 and TRE1 may be deteriorated by external light.

In the current embodiment, since the openings OP do not overlap the first circuit transistor TRS1 disposed in the first circuit part CP1 and do not overlap the second circuit transistor TRE1 disposed in the second circuit part CP2, deterioration of the circuit transistors due to external light can be prevented.

Display devices according to other embodiments will now be described with reference to other drawings.

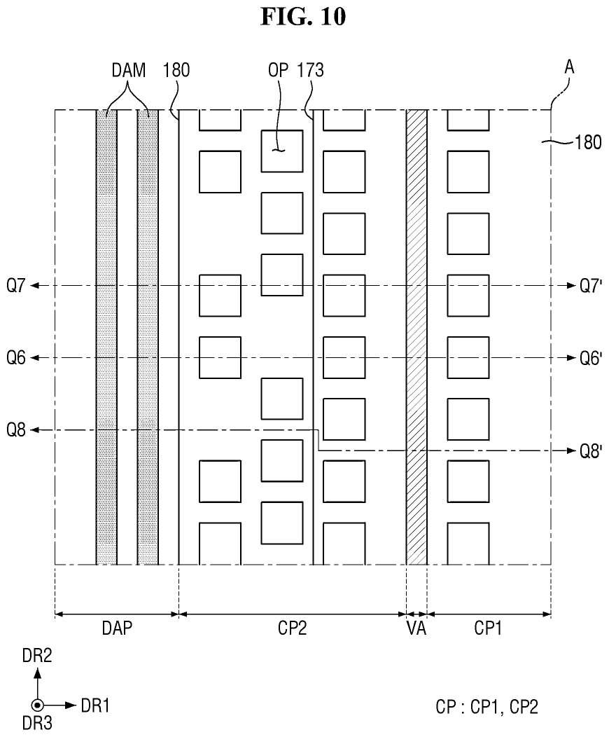

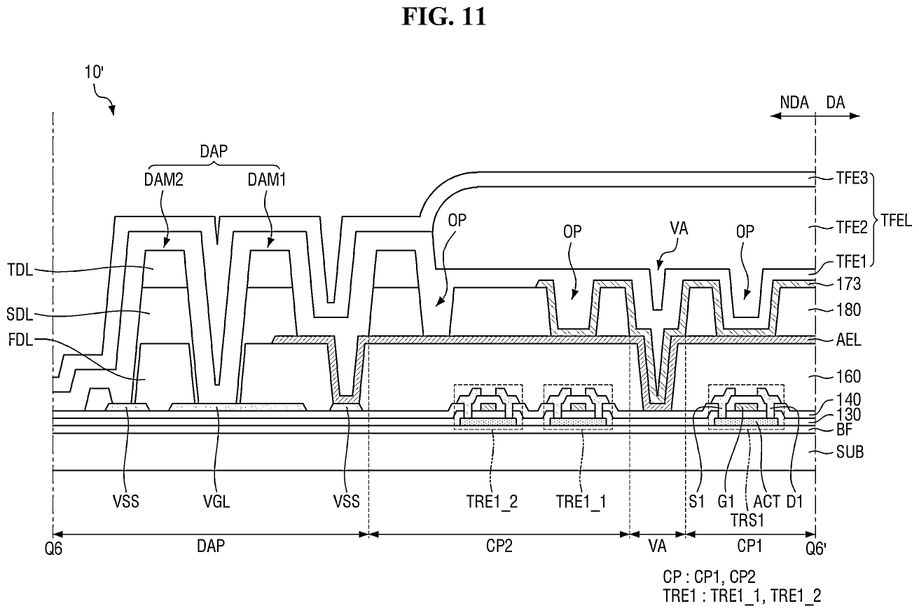

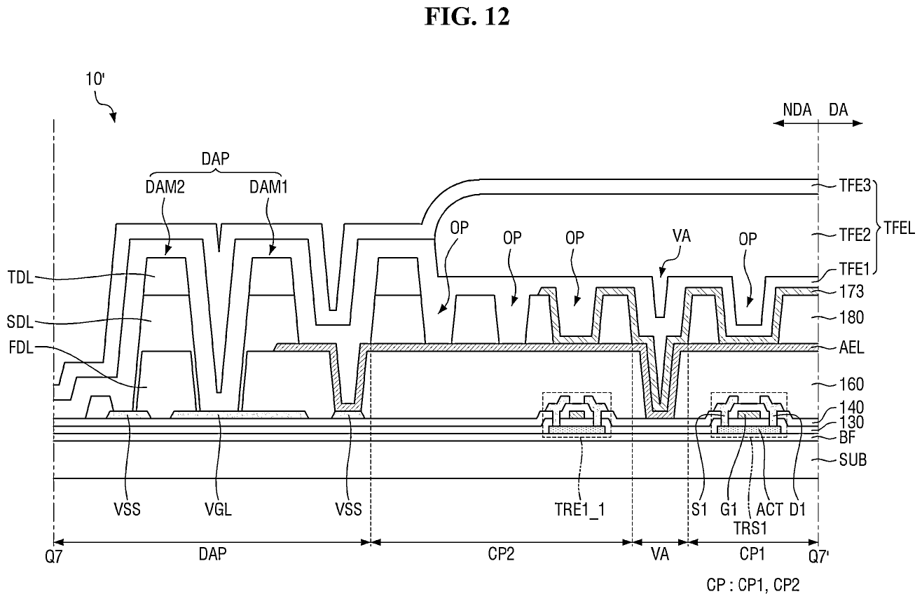

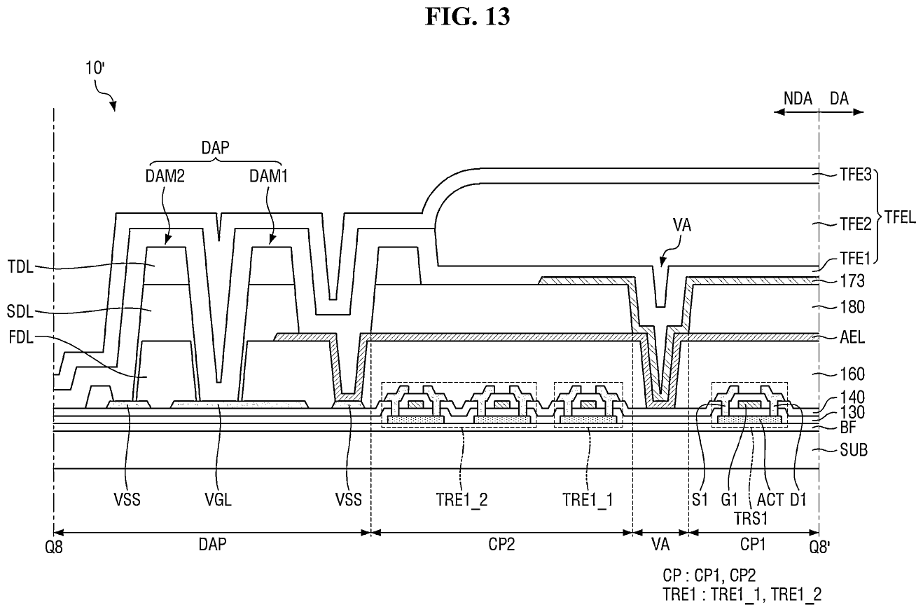

FIG. 10 is a plan view of a non-display area NDA of a display device 10′ according to an embodiment. FIG. 11 is a schematic cross-sectional view taken along line Q6-Q6′ of FIG. 10. FIG. 12 is a schematic cross-sectional view taken along line Q7-Q7′ of FIG. 10. FIG. 13 is a schematic cross-sectional view taken along line Q8-Q8′ of FIG. 10.

Referring to FIGS. 10 through 13, the current embodiment may be different from the above-described embodiment of FIGS. 6 through 9 in that multiple openings OP of a pixel defining layer 180 may overlap transistors of circuit parts CP in an area overlapping a common electrode 173. A description of the same elements as those of the above-described embodiment will be omitted or given briefly, and differences will be described below.

The circuit parts CP, a groove part VA, and a dam part DAP may be disposed on a substrate SUB in the non-display area NDA of the display device 10′.

Specifically, multiple transistors TRS1 and TRE1 may be disposed in the circuit parts CP. A first circuit transistor TRS1 may be disposed in a first circuit part CP1, and a second circuit transistor TRE1 may be disposed in a second circuit part CP2. A via layer 160 covering the first circuit transistor TRS1 and the second circuit transistor TRE1 may be disposed on the circuit parts CP, and a connection line AEL may be disposed on the via layer 160. The connection line AEL may extend from a display area DA to the non-display area NDA and may overlap the first circuit transistor TRS1 and the second circuit transistor TRE1 disposed under the via layer 160.

The pixel defining layer 180 may be disposed on the via layer 160 and the connection line AEL, and the common electrode 173 may be disposed on the pixel defining layer 180. The common electrode 173 may extend from the display area DA to the non-display area NDA. For example, the common electrode 173 may be disposed on the first circuit part CP1, the groove part VA, and the second circuit part CP2. The common electrode 173 may extend to at least a portion of the second circuit part CP2.

The common electrode 173 may overlap the entire first circuit part CP1 and may overlap at least a portion of the second circuit part CP2. For example, the common electrode 173 may overlap multiple first transistors TRS1 disposed in the first circuit part CP1. The common electrode 173 may overlap at least some of the second transistors TRE1 disposed in the second circuit part CP2.

The second circuit part CP2 may include (2-1)^{th} circuit transistors TRE1_1 adjacent to the first circuit part CP1 and (2-2)^{th} circuit transistors TREL_2 disposed adjacent to an outer side of the substrate SUB from the (2-1)^{th} circuit transistors TRE1_1. The common electrode 173 may overlap the (2-1)^{th} circuit transistors TRE1_1 and may not overlap the (2-2)^{th} circuit transistors TRE1_2.

The pixel defining layer 180 may include multiple openings OP. The openings OP may be disposed in the circuit parts CP. For example, the openings OP may be disposed in the first circuit part CP1 and the second circuit part CP2. The openings OP may be irregularly disposed in a plan view. For example, at least some of the openings OP may be disposed at equal intervals in the first direction DR1 and the second direction DR2 in a plan view, and other openings OP may be disposed at different intervals in the first direction DR1 or the second direction DR2.

In an embodiment, the openings OP may overlap some circuit transistors that overlap the common electrode 173 among the circuit transistors TRS1 and TRE1 disposed in the circuit parts CP and may not overlap other circuit transistors that do not overlap the common electrode 173. Specifically, the openings OP may overlap at least some of the first circuit transistors TRS1 disposed in the first circuit part CP1. For example, the openings OP may be disposed at intervals (e.g., predetermined or selectable intervals) in consideration of a process margin. Here, in case that a first circuit transistor TRS1 is disposed in a gap between the openings OP, the openings OP and the first circuit transistor TRS1 may not overlap each other as illustrated in FIG. 13. The other first circuit transistors TRS1 may overlap the openings OP as illustrated in FIGS. 11 and 12.

The openings OP may overlap some circuit transistors that overlap the common electrode 173 among the second circuit transistors TRE1 disposed in the second circuit part CP2 and may not overlap circuit transistors that do not overlap the common electrode 173. For example, the openings OP may overlap some of the (2-1)^{th} circuit transistors TRE1_1 that overlap the common electrode 173. As described above, in case that some (2-1)^{th} circuit transistors TRE1_1 are disposed in gaps between the openings OP, the openings OP and the (2-1)^{th} circuit transistors TRE1_1 may not overlap each other. The openings OP may not overlap the (2-2)^{th} circuit transistors TREL_2 disposed in the second circuit part CP2.

The common electrode 173 may include a metal material to reflect at least some light. For example, since the common electrode 173 covers the circuit parts CP, it can prevent at least a portion of light incident from the outside from entering the circuit parts CP. Therefore, relatively little external light may be incident on circuit transistors TRS1 and TRE1 of the circuit parts CP which overlap the common electrode 173. Accordingly, even in case that the openings OP of the pixel defining layer 180 and the circuit transistors TRS1 and TRE1 overlap, deterioration of the circuit transistors TRS1 and TRE1 due to external light can be reduced.

On the other hand, external light may be incident (e.g., directly incident) on circuit transistors TRE1 (i.e., the (2-2)^{th} circuit transistors TRE1_2) that do not overlap the common electrode 173. Therefore, these circuit transistors TRE1 may be disposed not to overlap the openings OP. For example, since the (2-2)^{th} circuit transistors TRE_2 overlap the black pixel defining layer 180, their deterioration due to external light can be prevented.

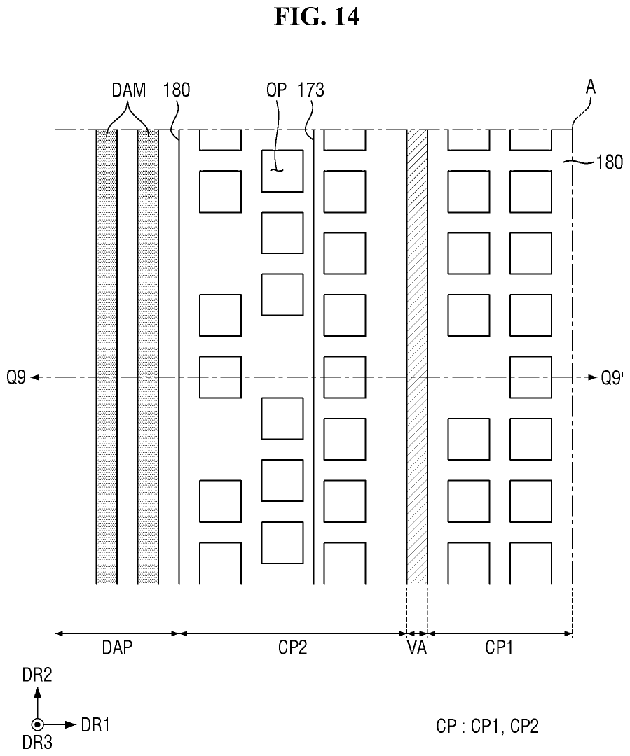

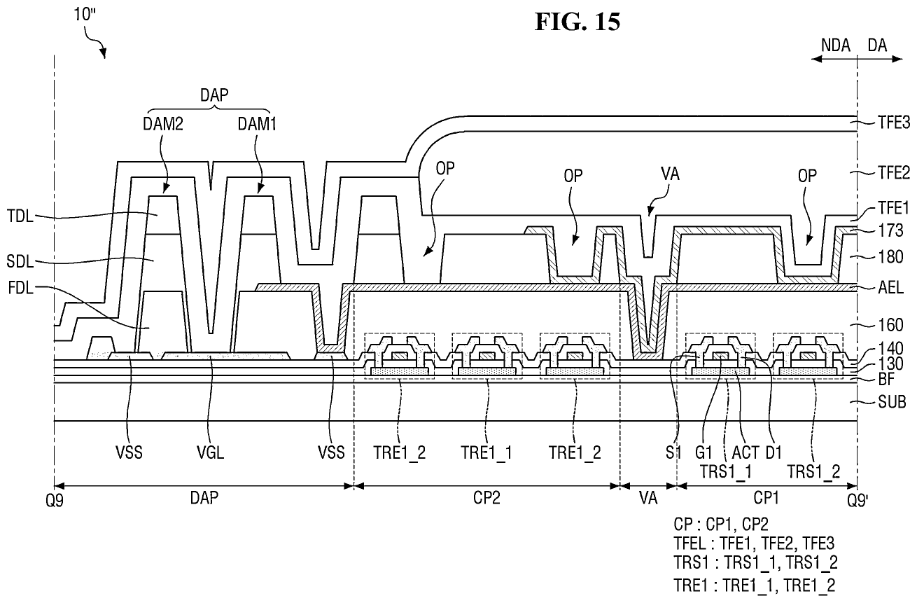

FIG. 14 is a plan view of a non-display area NDA of a display device 10″ according to an embodiment. FIG. 15 is a schematic cross-sectional view taken along line Q9-Q9′ of FIG. 14.

Referring to FIGS. 14 and 15, the current embodiment may be different from the above-described embodiments of FIGS. 6 through 13 in that buffer transistors among circuit transistors TRS1 and TRE1 of circuit parts CP do not overlap multiple openings OP of a pixel defining layer 180. A description of the same elements as those of the above-described embodiments will be omitted or given briefly, and differences will be described below.

The circuit parts CP, a groove part VA, and a dam part DAP may be disposed on a substrate SUB in the non-display area NDA of the display device 10″.

Specifically, multiple transistors TRS1 and TRE1 may be disposed in the circuit parts CP. First circuit transistors TRS1 may be disposed in a first circuit part CP1, and second circuit transistors TRE1 may be disposed in a second circuit part CP2.

The first circuit part CP1 may include (1-1)^{th} circuit transistors TRS1_1 and (1-2)^{th} circuit transistors TRS1_2. The (1-1)^{th} circuit transistors TRSL_1 may be buffer transistors. The buffer transistors may equally transmit an input voltage and an output voltage in each of the circuit parts CP1 and CP2. The (1-2)^{th} circuit transistors TRS1_2 may be switching transistors other than the buffer transistors.

The second circuit part CP2 may include (2-1)^{th} circuit transistors TRE1_1 and (2-2)^{th} circuit transistors TRE1_2. The (2-1)^{th} circuit transistors TRE1_1 may be buffer transistors. The (2-2)^{th} circuit transistors TRE1_2 may be switching transistors other than the buffer transistors.

The (1-1)^{th} circuit transistors TRS1_1 and the (2-1)^{th} circuit transistors TRE1_1 may have a relatively larger active layer ACT than the (1-2)^{th} circuit transistors TRS1_2 and the (2-2)^{th} circuit transistors TRE1_2. For example, since the (1-1)^{th} circuit transistors TRS1_1 and the (2-1)^{th} circuit transistors TRE1_1 have a large active layer ACT, their deterioration due to external light may be more fatal.

In the current embodiment, the (1-1)^{th} circuit transistors TRS1_1 and the (2-1)^{th} circuit transistors TRE1_1 in the circuit parts CP1 and CP2 may be disposed not to overlap the openings OP of the pixel defining layer 180. Therefore, the (1-1)^{th} circuit transistors TRS1_1 and the (2-1)^{th} circuit transistors TRE1_1 can be prevented from being deteriorated by external light.

Specifically, in the first circuit part CP1, the (1-1)^{th} circuit transistors TRS1_1 may overlap the pixel defining layer 180, and the black pixel defining layer 180 may prevent external light from entering the (1-1)^{th} circuit transistors TRS1_1. The (1-2)^{th} circuit transistors TRS1_2 may overlap the openings OP of the pixel defining layer 180.

The (1-1)^{th} circuit transistors TRS1_1 and the (1-2)^{th} circuit transistors TRS1_2 disposed in the first circuit part CP1 may overlap a common electrode 173. Since the (1-1)^{th} circuit transistors TRS1_1 overlap the common electrode 173 and the pixel defining layer 180, their active layers ACT can be prevented from being deteriorated by external light. The (1-2)^{th} circuit transistors TRS1_2 overlapping the openings OP may be blocked from at least a portion of external light by the common electrode 173. Thus, deterioration of their active layers ACT by the external light can be reduced.

In the second circuit part CP2, the (2-1)^{th} circuit transistors TRE1_1 may overlap the pixel defining layer 180, and the black pixel defining layer 180 may prevent external light from entering the (2-1)^{th} circuit transistors TRE1_1. Therefore, since the (2-1)^{th} circuit transistors TRE1_1 overlap the pixel defining layer 180, their active layers ACT can be prevented from being deteriorated by external light.

The (2-2)^{th} circuit transistors TRE1_2 may overlap the openings OP of the pixel defining layer 180. At least some of the (2-2)^{th} circuit transistors TREL_2 may overlap the common electrode 173. For example, the (2-2)^{th} circuit transistors TREL_2 may overlap the common electrode 173 and the openings OP. The (2-2)^{th} circuit transistors TRE1_2 overlapping the openings OP may be blocked from at least a portion of external light by the common electrode 173. Thus, deterioration of their active layers ACT by the external light can be reduced.

In a display device according to an embodiment, openings of a pixel defining layer do not overlap circuit transistors disposed in a circuit part in a non-display area. Therefore, the circuit transistors can be prevented from being deteriorated by external light.

Circuit transistors overlapping a common electrode in the non-display area may overlap the openings, and circuit transistors that do not overlap the common electrode do not overlap the openings. Therefore, the circuit transistors can be prevented from being deteriorated by external light.

The openings of the pixel defining layer do not overlap buffer transistors among the circuit transistors disposed in the circuit part in the non-display area. Therefore, the buffer transistors can be prevented from being deteriorated by external light.

However, the effects of the disclosure may not be restricted to the one set forth herein. The above and other effects of the disclosure will become more apparent to one of daily skill in the art to which the disclosure pertains by referencing the claims.

In concluding the detailed description, those skilled in the art will appreciate that many variations and modifications can be made to the embodiments without substantially departing from the principles of the disclosure. Therefore, the disclosed embodiments of the disclosure may be used in a generic and descriptive sense only and not for purposes of limitation.

What is claimed is:

1. A display device comprising:
a display area and a non-display area;
a light emitting element layer disposed on a substrate in the display area and comprising a pixel electrode, an organic light emitting layer and a common electrode;
a circuit part disposed on the substrate in the non-display area and comprising a plurality of circuit transistors; and
a pixel defining layer extending from the display area to the circuit part, wherein
the pixel defining layer comprises a plurality of openings overlapping the circuit part, and
the plurality of openings do not overlap the plurality of circuit transistors.

2. The display device of claim 1, wherein the pixel defining layer covers edges of the pixel electrode and comprises a black pigment or dye.

3. The display device of claim 1, wherein ones of the plurality of circuit transistors that do not overlap the openings among the plurality of circuit transistors overlap the pixel defining layer.

4. The display device of claim 1, wherein a distance between any two adjacent openings among the plurality of openings varies.

5. The display device of claim 1, wherein a distance between any two adjacent openings among the plurality of openings is greater than a distance between two other openings.

6. The display device of claim 1, wherein the plurality of circuit transistors comprise an oxide semiconductor.

7. The display device of claim 1, further comprising:
a via layer disposed on the display area and the non-display area and disposed between the substrate and the pixel defining layer,
wherein the plurality of openings expose an upper surface of the via layer.

8. The display device of claim 1, wherein the common electrode extends from the display area to the circuit part and overlaps at least some of the plurality of circuit transistors.

9. A display device comprising:
a display area and a non-display area;
a light emitting element layer disposed on a substrate in the display area and comprising a pixel electrode, an organic light emitting layer and a common electrode;
a plurality of circuit parts disposed on the substrate in the non-display area and comprising a plurality of circuit transistors; and
a pixel defining layer extending from the display area to the plurality of circuit parts, wherein
the common electrode extends from the display area to the circuit parts,
the pixel defining layer comprises a plurality of openings overlapping the plurality of circuit parts,
some of the plurality of circuit transistors overlap the common electrode,
the plurality of openings overlap at least some of the plurality of circuit transistors that overlap the common electrode, and
the plurality of openings do not overlap any of the plurality of circuit transistors that do not overlap the common electrode.

10. The display device of claim 9, wherein
the plurality of circuit parts comprise a first circuit part disposed adjacent to the display area and a second circuit part spaced farther apart from the display area than the first circuit part,
the first circuit part comprises a plurality of first circuit transistors, and
the common electrode overlaps each of the plurality of first circuit transistors.

11. The display device of claim 10, wherein
the second circuit part comprises (2-1)th circuit transistors adjacent to the first circuit part and (2-2)th circuit transistors disposed between an outer side of the substrate and the (2-1)th circuit transistors, and
the common electrode overlaps the (2-1)th circuit transistors and does not overlap the (2-2)th circuit transistors.

12. The display device of claim 11, wherein the plurality of openings overlap at least some of the first circuit transistors and at least some of the (2-1)-th circuit transistors.

13. The display device of claim 12, wherein the openings do not overlap any of the (2-2)th circuit transistors.

14. A display device comprising:
a display area and a non-display area;
a light emitting element layer disposed on a substrate in the display area and comprising a pixel electrode, an organic light emitting layer and a common electrode;
a plurality of circuit parts disposed on the substrate in the non-display area and comprising a plurality of circuit transistors; and
a pixel defining layer extending from the display area to the plurality of circuit parts and comprising a plurality of openings overlapping the plurality of circuit parts,
wherein the plurality of openings overlap some of the plurality of circuit transistors and do not overlap the other circuit transistors.

15. The display device of claim 14, wherein
the plurality of circuit parts comprise a first circuit part disposed adjacent to the display area and a second circuit part spaced farther apart from the display area than the first circuit part,
each of the first circuit part and the second circuit part comprises a plurality of buffer transistors, and
the plurality of buffer transistors of each of the first and second circuit parts do not overlap any of the plurality of openings.

16. The display device of claim 15, wherein
each of the first circuit part and the second circuit part further comprises a plurality of switching transistors, and
some of the switching transistors of each of the first circuit part and the second circuit part overlap ones of the plurality of openings, and the other switching transistors overlap the pixel defining layer.

17. The display device of claim 15, wherein
the common electrode extends from the display area to overlap the first circuit part and the second circuit part,
the plurality of buffer transistors disposed in the first circuit part overlap the common electrode, and
at least some of the buffer transistors disposed in the second circuit part do not overlap the common electrode.

18. The display device of claim 14, wherein the plurality of circuit transistors comprise an oxide semiconductor.

19. The display device of claim 14, further comprising:
a via layer disposed between the substrate and the pixel defining layer and covering the plurality of circuit transistors; and
a connection line disposed between the pixel defining layer and the via layer and overlapping the plurality of circuit transistors.

20. The display device of claim 14, further comprising
a thin-film encapsulation layer disposed on the light emitting element layer and extending from the display area to the non-display area,
wherein the thin-film encapsulation layer overlaps the plurality of circuit transistors.
